(19) United States
(12) Patent Application Publication
(10) Pub. No.: US 2025/0178042 A1
(43) Pub. Date: Jun. 5, 2025

(54) Supercritical Fluid Cleaning for Components in Optical or Electron Beam Systems

(71) Applicant: KLA Corporation, Milpitas, CA (US)

(72) Inventors: Jiulong Sun, Singapore (SG); Eric Jiang, Singapore (SG); Ali Ehsani, San Ramon, CA (US); Garry Rose, Livermore, CA (US); Boyd Taylor, Patterson, CA (US)

(21) Appl. No.: 19/052,241

(22) Filed: Feb. 12, 2025

Related U.S. Application Data
(62) Division of application No. 18/078,913, filed on Dec. 9, 2022.
(60) Provisional application No. 63/292,508, filed on Dec. 22, 2021.

(51) Int. Cl. B08B 7/00; C11D 7/16; C11D 7/32; C11D 7/50; H01L 21/02

(52) U.S. Cl. CPC B08B 7/0021; C11D 7/16; C11D 7/3209; C11D 7/50; C11D 2111/22; H01L 21/02101

(57) ABSTRACT

To clean components in semiconductor manufacturing equipment, such as an optical system or an electron beam system, a component is heated in a chamber. A supercritical fluid formulation is applied to the component in the chamber, which removes molecular and/or particulate contaminants. The supercritical fluid formulation can include one or more of carbon dioxide, water, HCF, alkane, alkene, nitrous oxide, methanol, ethanol, or acetone.

### CROSS-REFERENCE TO RELATED APPLICATIONS

This application is a divisional application of U.S. application Ser. No. 18/078,913 filed on Dec. 9, 2022, which claims priority to the provisional patent application filed Dec. 22, 2021 and assigned U.S. App. No. 63/292,508, the disclosures of which are hereby incorporated by reference.

### FIELD OF THE DISCLOSURE

This disclosure relates to cleaning components of semiconductor manufacturing equipment.

### BACKGROUND OF THE DISCLOSURE

Semiconductor manufacturing equipment is used to fabricate semiconductor devices. Contaminants from semiconductor manufacturing equipment often contaminates the semiconductor wafers. For example, contaminants such as photoresist and polymer residues can contaminate semiconductor devices, which can affect device performance and reduce product yield. Currently, a variety of wet (e.g., deionized water and solvent) and dry (e.g., plasma) cleaning processes have been developed to address the broad variety of contaminants. However, current cleaning methods for semiconductor device fabrication equipment are often not effective in thoroughly cleaning semiconductor manufacturing equipment.

In particular, inspection or metrology tools can include an optical beam system or an electron beam system. Cleanliness of components is important with, for example, an optical or electron beam source. Contaminants from an uncleaned component can damage the system and can result in non-functioning equipment due to the interaction between the contaminant and the high energy of photons or the electron beam. For example, contaminants such as cutting fluid or coolant from a machining process can contaminate an optical or electron beam system.

The flowchart in FIG. 1 shows a previous wet cleaning technique. Isopropanol (IPA) or another solvent was used to remove particles, oil, and grease during a solvent rinse. Ultrasonic cleaning was applied with IPA or another solvent to further remove contaminants. Deionized water (DIW) was used to rinse and the component was dried in clean dry air (CDA). An ultrasonic rinse with aqueous degreaser solution further removed contaminants. A deionized water (DIW) low pressure spray rinse and soak was used to remove residuals, followed by drying in CDA.

The chemicals in this previous technique have difficulty accessing tiny holes, blind holes, and microstructures of components. Meeting the cleaning specifications was difficult due to large surface tension and high viscosity of chemicals. Contaminants from previous cleaning processes can be re-introduced because of the number of chemicals involved. Therefore, the effectiveness of the cleaning is insufficient. Besides problems with effectiveness, the reliability of previous technique is poor because there is significant manual operation involved during the wet cleaning process. The maintenance requirements for the process instruments also are high. The amount of chemicals and water used in the previous technique is neither cost-effective nor environmentally-friendly.

Therefore, improved techniques and systems are needed.

### BRIEF SUMMARY OF THE DISCLOSURE

A cleaning method is provided in a first embodiment. The cleaning method includes heating a component of an optical system or an electron beam system in a chamber. A supercritical fluid formulation is applied to the component in the chamber thereby removing molecular and/or particulate contaminants. The supercritical fluid formulation includes one or more of carbon dioxide, water, HCF, alkane, alkene, nitrous oxide, methanol, ethanol, or acetone. In an instance, the supercritical fluid formulation includes carbon dioxide.

The supercritical fluid formulation can include a co-solvent that includes one or more of an alcohol, an ether, a thiol, a ketone, a hydrocarbon, a nitrile, an amide, an aromatic compound, an aprotic solvent, HFC, DMF, or NMP.

The supercritical fluid formulation can include a surfactant that includes one or more of acetyl acetone, hexafluoro acetyl acetone, an acetylenic alcohol, a diol, a long alkyl chain secondary amine, or a tertiary amine.

The supercritical fluid formulation can include a chelating agent that includes one or more of citric acid, EDTA, oxalic acid, a polycarboxylic acid, a substituted dithiocarbamate, a malonic acid ester, or polyethylene glycol.

The supercritical fluid formulation can include an oxidant that includes one or more of ozone or hydrogen peroxide.

The supercritical fluid formulation can include a dispersant that includes one or more of sodium tripolyphosphate or a quaternary ammonium salt.

The component can be a laser source, an x-ray light source, a DUV source, an EUV source, an illumination optics, a collection optics, or a broadband plasma and laser cavity. In another instance, the component can be an electron gun system, an electron column system, a vacuum chamber, or a platform. In another instance the component is an optics that includes CLBO, BBO, KTP, PPKTP, LBO, DKDP, ADP, KDP, LiIO₃, KNbO₃, LiNbO₃, AgGaS₂, AgGaSe₂, MgF₂, CaF₂, BaF₂, LiF, YAG, TGG, TiO₂, ZnS, ZnSe, GaAs, or SiGe. In another instance, the component is a crystal that includes an oxide coating, Ta₂O₅, ZrO₂, HfO₂, Al₂O₃, SiO₂, Nb₂O₅, TiO₂, FS, SBO, a fluoride coating, LiF, CaF₂, MgF₂, LaF₃, AlF₃, LiF, LaF₃, GdF₃, or NdF₃. In another instance, the component is a precision aperture, pneumatic delivering system, electron beam aperture, vacuum compatible mechanics, or an optomechanics. In another instance, the component is a cable, PCB, sensor, PZT, electron beam deflector, electrostatic lens, or pin-diode. In another instance, the component is an LED, emitter, TDI, CCD, or CMOS. In another instance, the component is a sealing material, and wherein the sealing material includes indium, copper, silver, or a polymer.

The component can be passivated after applying the supercritical fluid formulation.

A cleaning system is provided in a second embodiment. The cleaning system includes a supercritical fluid chamber configured to hold a component that is cleaned; a CO₂ tank; a fluid line connecting the CO₂ tank to the supercritical fluid chamber; a heater disposed on the supercritical fluid chamber that is configured to heat the component; and a pump disposed on the fluid line configured to pressurize CO₂ from the CO₂ tank. The heater and the pump are configured to operate such that the CO₂ is applied to the component as supercritical CO₂.

The cleaning system can include a CO₂ recycle system in fluid communication with the supercritical fluid chamber and the CO₂ tank.

The cleaning system can include an additional tank in fluid communication with the fluid line. The additional tank can hold one or more of a co-solvent, a surfactant, a chelating agent, an oxidant, or a dispersant.

### DESCRIPTION OF THE DRAWINGS

For a fuller understanding of the nature and objects of the disclosure, reference should be made to the following detailed description taken in conjunction with the accompanying drawings, in which:

FIG. 1 is a flowchart of a previous wet cleaning technique;

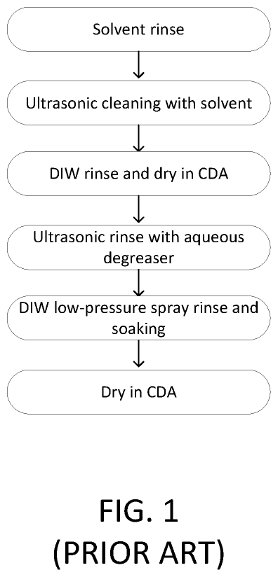

FIG. 2 is a phase diagram for CO₂;

FIG. 3 is a flowchart of a method embodiment in accordance with the present disclosure;

FIG. 4 is a block diagram of an embodiment of a system in accordance with the present disclosure;

FIG. 5 is a table showing exemplary recipes using CO₂; and

FIG. 6 is a table of test results.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments disclosed herein use supercritical fluid (SCF) cleaning to provide more reliable cleaning performance and improved cleaning results for critical and/or challenging components, such as those with complex geometries, tight spaces, or microstructures. The SCF cleaning formulation is used to clean components and remove contaminants. This can reduce component failure and cross-contamination, enhance reliability and lifetime, and/or maintain tool sensitivity and performance. The component that is cleaned can be used in semiconductor manufacturing equipment, such as inspection or metrology tools. Thus, the component can be part of an optical beam system or an electron beam system.

Embodiments disclosed herein are directed to a process of cleaning an optical system or an electron beam system. In an embodiment, a component of the optical system or electron beam system is placed in a chamber; a fluid is introduced into the chamber; a pressure and temperature of the fluid is controlled to bring the fluid to a supercritical state; the component is cleaned by having the supercritical fluid contact the component; the supercritical fluid is removed from the chamber; and the component is removed from the chamber.

Carbon dioxide in its supercritical fluid state has been used a replacement for organic solvents used in cleaning applications. Supercritical carbon dioxide offers the unique properties of supercritical fluids with reduced environmental risks to the water supply. Carbon dioxide is removed as a gas when exposed to ambient conditions and can be recycled. For substances which exhibit supercritical fluid properties, when the substance is above its critical point (critical temperature and critical pressure), the phase boundary between the gas phase and liquid phase disappears, and the substance exists in a single supercritical fluid phase. In the supercritical fluid phase, a substance assumes some of the properties of a gas and some of the properties of a liquid. For example, SCFs have diffusivity properties similar to gases but solvating properties similar to liquids, being able to penetrate into spaces that traditional solvents cannot reach. Thus, SCFs have beneficial cleaning properties.

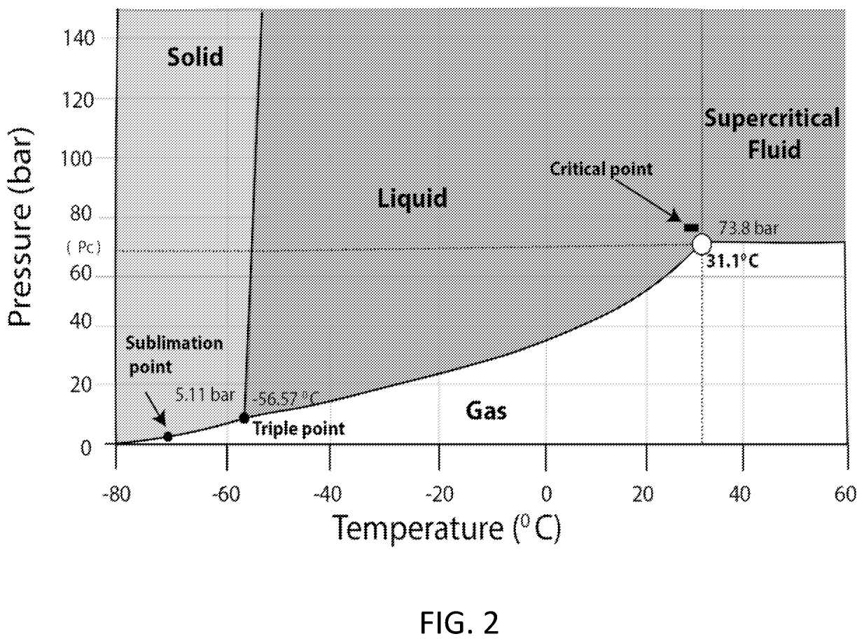

Supercritical CO₂ can clean the components of optical or electron beam system. FIG. 2 shows a phase diagram for CO₂. The SCF presents both gas-like transport properties and liquid-like solvent properties, which provides improved cleaning capability and efficiency.

Supercritical CO₂ can offer zero surface tension, which allows the SCF to better penetrate into fine-scale structure such as high aspect ratio vias, small gaps, tiny blind holes, or micropores without need for brushing/agitation to clean complex geometries and tight spaces of a component. Ultrasonic or agitation can be still applied during certain applications.

Supercritical CO₂ also has a liquid-like density, which allows high mass transfer during cleaning. When coupled with supercritical CO₂'s affinity with organic contaminants because it is a nonpolar solvent, cleaning results can be improved compared to previous techniques. Supercritical CO₂'s has low viscosity and high diffusivity can provide faster transport and shorter processing during cleaning.

In an embodiment, temperature is tunable to provide a sufficient driving force for cleaning. This can provide a one-step cleaning process that can address multiple different contaminant types. A supercritical fluid can clean both molecular and particulate contaminants because surface tension is broken. The contaminants can be, for example, volatile organic compounds and/or siloxane, which can be produced during machining, handling, or packaging processes. Of course, other contaminants are possible and these are merely examples.

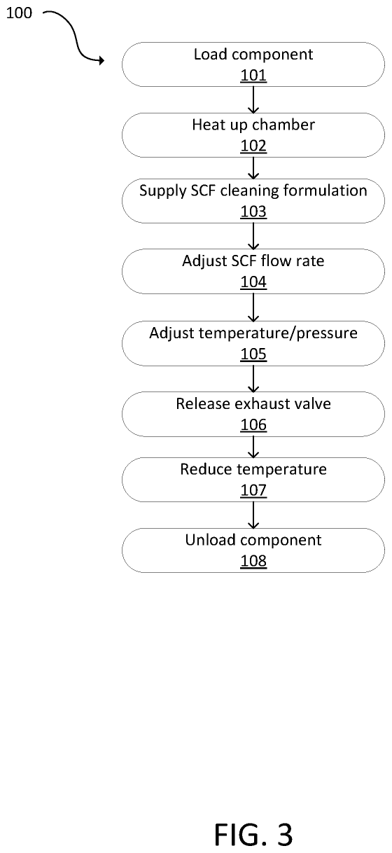

FIG. 3 is a flowchart of a cleaning method 100. A component is loaded in to a chamber at 101. The component can be part of an optical system or an electron beam system. At 102, the chamber is heated up to a desired temperature. The temperature can be between 40° C. to 180° C. or, more particularly, 80° C. to 120° C. Other temperature ranges are possible based on the component or the supercritical fluid cleaning formulation.

The supercritical fluid cleaning formulation is supplied to the chamber at a target pressure at 103 to remove molecular and/or particulate contaminants. The pressure can be, for example, from 100 bar to 300 bar, though the exact pressure can depend on the supercritical fluid cleaning formulation and the temperature of the chamber. Effective cleaning can improve the lifetime of the component. A valve can be adjusted at 104 to adjust the supercritical fluid cleaning formulation flow rate. This can flush out contaminants carried by the supercritical fluid cleaning formulation away from the component or out of the chamber. Fresh supercritical fluid cleaning formulation can be supplied to maintain pressure around the component or in the chamber.

An agitation may optionally be applied to accelerate diffusion of contaminants into the supercritical fluid.

In an instance, the supercritical fluid cleaning formulation is subject to ultrasonication, stirring, a pulse (i.e., a pressure/temperature change), or combinations of thereof before or during its application to the component. This can accelerate how quickly the contaminants dissolve in the supercritical fluid cleaning formulation. The ultrasonic frequency can be greater than 25 KHZ. The sitting speed can be greater than 60 rpm. The pressure/temperature change can be from 10% to 30%

A temperature profile and/or pressure profile can be applied. Temperature and/or pressure can be adjusted as necessary at 105. The cleaning cycle can be 10 minutes to 60 minutes per cycle, though other durations are possible. Two cycles per run may be performed.

An exhaust valve is released at 106 to normalize pressure. Temperature can be reduced at 107, such as to room temperature. The component can be unloaded from the chamber at 108.

The supercritical fluid formulation includes one or more of carbon dioxide, water, a fluoroform (HCF), alkane, alkene, nitrous oxide, methanol, ethanol, or acetone. In an instance, the supercritical fluid formulation includes carbon dioxide with or without additional species. For example, using carbon dioxide with an alcohol or acetone can improve cleaning because alcohol and acetone can affect polarity. The supercritical fluid formulation optionally can include one or more of a co-solvent, a surfactant, a chelating agent, an oxidant, or a dispersant.

The supercritical fluid formulation can include a co-solvent that includes or that is one or more of an alcohol, an ether, a thiol, a ketone, a hydrocarbon, a nitrile, an amide, an aromatic compound, an aprotic solvent, hydrofluorocarbon (HFC), dimethylformamide (DMF), or n-methyl-2-pyrrolidone (NMP). The co-solvent can change system polarity and affect contaminant dissolving behaviors such as solubility or dissolving rate. In an instance, alcohol, ketone, and/or DMF are used in our process at a non-zero mass or volume percentage of less than 5% of the supercritical fluid formulation.

The supercritical fluid formulation can include a surfactant that includes or that is one or more of acetyl acetone, hexafluoro acetyl acetone, an acetylenic alcohol, a diol, a long alkyl chain secondary amine, or a tertiary amine. The surfactant can decrease surface tension between a liquid and a solid or two liquids. The surfactant can be added at a non-zero mass or volume percentage of less than 15% of the supercritical fluid formulation.

The supercritical fluid formulation can include a chelating agent that includes or that is one or more of citric acid, ethylenediaminetetraacetic acid (EDTA), oxalic acid, a polycarboxylic acid, a substituted dithiocarbamate, a malonic acid ester, or a polyethylene glycol. The chelating agent can bond to metal ions. The chelating agent can be added at a non-zero mass or volume percentage of less than 3% of the supercritical fluid formulation.

The supercritical fluid formulation can include an oxidant that includes or that is one or more of ozone or hydrogen peroxide. For example, hydrogen peroxide can oxidize organic contaminants to CO₂ and water. Ozone or hydrogen peroxide can be added at a non-zero mass or volume percentage of less than 5% of the supercritical fluid formulation.

The supercritical fluid formulation can include a dispersant that includes or that is one or more of sodium tripolyphosphate or a quaternary ammonium salt. The dispersant can be added at a non-zero mass or volume percentage of less than 3% of the supercritical fluid formulation.

The supercritical fluid formulation can depend on the cleaning application. Pure CO₂, CO₂ with a co-solvent, and CO₂ with an oxidant can effectively remove contaminants.

The component may be passivated after the cleaning. This can be performed in a separate system from that used to clean the component. Oxygen can be introduced to passivate the component at high temperature from 80° C. to 180° C. to reduce component surface free energy. For example, metal components may need to be passivated after the cleaning before use.

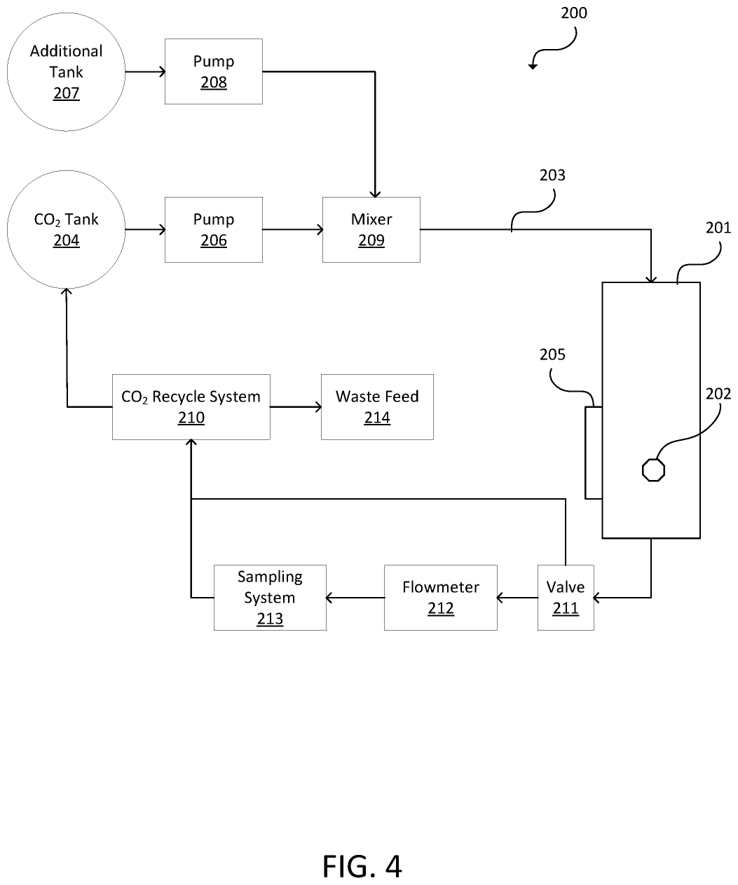

FIG. 4 is a block diagram of cleaning system 200. The cleaning system 200 can be used to perform the various embodiments of the cleaning method 100. While CO₂ is used as the exemplary supercritical fluid in the description of FIG. 4, other supercritical fluids or mixtures of supercritical fluids with or without other chemicals may be used.

The cleaning system 200 includes a supercritical fluid chamber 201 that holds a component 202 that is cleaned. The supercritical fluid chamber 201 can include a heater 205 that can heat the component 202 or the supercritical fluid chamber 201.

A fluid line 203 connects a CO₂ tank 204 to the supercritical fluid chamber 201.

A pump 206 is disposed on the fluid line 203 and is configured to pressurize CO₂ from the CO₂ tank 204. The heater 205 and the pump 206 can operate such that the CO₂ is applied to the component 202 as supercritical CO₂.

An additional tank 207 can hold a co-solvent, a surfactant, a chelating agent, an oxidant, a dispersant, or another species. The contents of the additional tank can be pressurized using the pump 208. The additional species can be added to the fluid line 203 using a mixer 209.

The cleaning system 200 can include a CO₂ recycle system 210 in fluid communication with the supercritical fluid chamber 201 and the CO₂ tank 204. A valve 211 can be opened to allow fluid flow to the flowmeter 212 and the sampling system 213. The CO₂ recycle system 210 separates contaminants, co-solvent, and other additives from the CO₂. CO₂ is sent from the CO₂ recycle system 210 to the CO₂ tank 204. Other species can be sent from the CO₂ recycle system to a waste feed 214. The waste feed 214 can safely dispose of the other species or can provide further separation.

A high level of cleanliness can be achieved when cleaning the component 202 with the cleaning system 200. This can be one to two orders of magnitude more than previous techniques. The cleaning can meet the Level 10 specification with more than 85% confidence. A Level 10 specification has a volatile organic concentration less than 5×10⁻⁴ ng/L/cm². Cycle time using the cleaning system 200 can be 1-4 hours per cycle. Introduction of additional contaminants can be avoided.

Alternatively, the fluid line 203 can be connected directly to a chamber in an optical system or an electron beam system. The chamber in the optical system or an electron beam system can be configured to withstand the pressure used during the cleaning process.

The component 202 can be a part of an optical or electron beam system. For example, the component 202 can be a laser source, an x-ray light source, a deep ultraviolet (DUV) source, an extreme ultraviolet (EUV) source, an illumination optics, a collection optics, or a broadband plasma and laser cavity from an optical system. The component 202 also can be an electron gun system, an electron column system, a vacuum chamber, or a platform from an electron beam system.

The component 202 also can be an optics, crystal, precision mechanical component, electronic component, semiconductor-based component, or sealing material. The optics can include or otherwise be fabricated of CLBO, BBO, KTP, PPKTP, LBO, DKDP, ADP, KDP, LiIO₃, KNbO₃, LiNbO₃, AgGaS₂, AgGaSe₂, MgF₂, CaF₂, BaF₂, LiF, YAG, TGG, TiO₂, ZnS, ZnSe, GaAs, or SiGe. The crystal can include an oxide coating, Ta₂O₅, ZrO₂, HfO₂, Al₂O₃, SiO₂, Nb₂O₅, TiO₂, FS, SBO, a fluoride coating (e.g., a water-sensitive fluoride coating), LiF, CaF₂, MgF₂, LaF₃, AlF₃, LiF, LaF₃, GdF₃, or NdF₃. The precision mechanical component can be a precision aperture, pneumatic delivering system, electron beam aperture, vacuum compatible mechanics, or an optomechanics. The electronic component can be a cable, printed circuit board (PCB), sensor (e.g., time delay and integration (TDI), avalanche photodiode (APD), PIN diode), a piezoelectric (PZT) component, electron beam deflector, electrostatic lens, or pin-diode. The semiconductor-based component can be a light-emitting diode (LED), emitter, TDI, charge-coupled device (CCD), or complementary metal-oxide-semiconductor (CMOS). The sealing material can include indium, copper, silver, or a polymer.

Many of these components 202 would be damaged using previous techniques. Embodiments disclosed herein can be used even for easily-damaged crystals or optics. Some of these components 202 are sensitive to water, which would damage its structure.

While specific examples of the component 202 are disclosed herein, other components that are part of semiconductor manufacturing tools can be cleaned.

In an example, an SP7 crystal cartridge was cleaned by supercritical fluid cleaning. The result showed that supercritical fluid cleaning is able to consistently to meet a Level 10 specification for a complex part. The SP7 crystal cartridge would not meet the Level 10 specification using old cleaning method alone. To meet the Level 10 specification, the SP7 crystal cartridge was cleaned with the old cleaning method followed by a high temperature baking, which resulted in long cycle time, high cost, and low reliability.

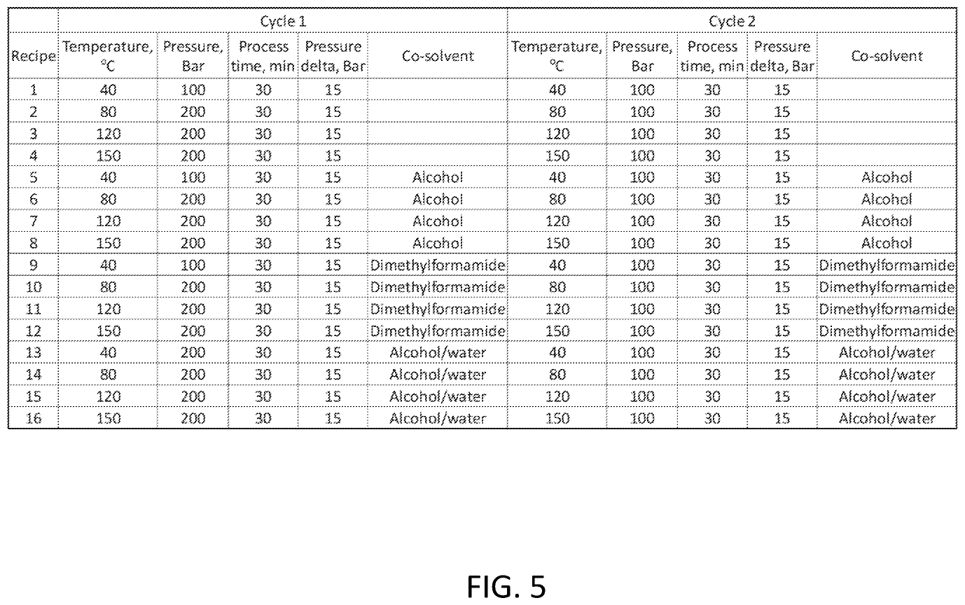

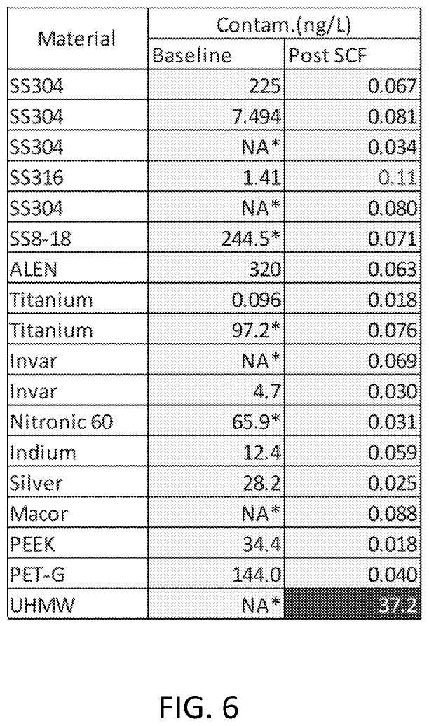

FIG. 5 is a table showing recipes using CO₂. The alcohol in these examples was methanol, ethanol, and/or isopropanol. The recipes were successfully tested against stainless steel (SS), aluminum, titanium, beryllium copper 17200, Invar, silver, indium, perfluoroalkoxy alkanes (PFA), Viton, ultra-high molecular weight polyethylene (UHMW PE), ultra-high molecular weight polypropylene (UHMW PP), Delrin AF, polyetheretherketon (PEEK), ertalyte polyethylene terephthalate (PET-P), Macor, and Nitronic 60. The recipes demonstrated a 100% pass rate for the contamination specification for metals and ceramics and an acceptable pass rate for plastics. For example, the metal components included manifolds, screws, clamps, plates, and gaskets. The plastic components included plates and shutters. FIG. 6 shows VOC results for the testing. The table in FIG. 6 compares the baseline contamination (contam.) against the values after supercritical fluid cleaning (“Post SCF”).

The examples presented herein are purely exemplary and are not meant to be limiting.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A cleaning method comprising:
heating a component of an optical system in a chamber, wherein the component is an optics; and
applying a supercritical fluid formulation to the component in the chamber thereby removing molecular and/or particulate contaminants, wherein the supercritical fluid formulation includes carbon dioxide and an alcohol.

2. The cleaning method of claim 1, wherein the alcohol is methanol, ethanol, and/or isopropanol.

3. The cleaning method of claim 1, wherein the supercritical fluid formulation does not include water.

4. The cleaning method of claim 1, wherein the optics includes a fluoride coating.

5. The cleaning method of claim 4, wherein the fluoride coating includes MgF₂, CaF₂, BaF₂, LiF, LaF₃, AlF₃, LaF₃, GdF₃, or NdF₃.

6. The cleaning method of claim 1, wherein the optics includes CLBO, SBO, BBO, LBO, or KDP.

7. The cleaning method of claim 1, further comprising passivating the component after the applying.
